(19) United States
(12) Patent Application Publication
(10) Pub. No.: US 2015/0194328 A1
(43) Pub. Date: Jul. 9, 2015

(54) LOAD PORT APPARATUS

(71) Applicant: TDK Corporation, Tokyo (JP)

(72) Inventors: Jun EMOTO, Tokyo (JP); Tadamasa IWAMOTO, Tokyo (JP)

(73) Assignee: TDK Corporation, Tokyo (JP)

(21) Appl. No.: 14/583,934

(22) Filed: Dec. 29, 2014

(30) Foreign Application Priority Data
Jan. 6, 2014 (JP) 2014-000100

(51) Int. Cl. H01L 21/677

(52) U.S. Cl. CPC H01L 21/67775; H01L 21/67772; H01L 21/67778

(57) ABSTRACT

Provided is a load port apparatus capable of suppressing leakage of an inert gas from a mini-environment. The load port apparatus includes: a main base configured to partition the mini-environment from an external space, the main base including an opening portion facing an opening of a pod and communicating the mini-environment to the external space; and a door configured to open and close the opening portion and hold a lid. With this, wafers are insertable and removable between the pod and the mini-environment. The load port apparatus further includes a flexible sealing plate arranged so as to project from the main base toward an inside of the opening portion, the flexible sealing plate being configured to abut against an abutment surface surrounding the opening of the pod.

### BACKGROUND OF THE INVENTION

1. Field of the Invention

The present invention relates to a load port apparatus. More specifically, the present invention relates to a load port apparatus configured to open and close a sealed transportation container, which is called a pod, when wafers held in the pod are transferred to a semiconductor processing apparatus in a semiconductor manufacturing process.

2. Description of the Related Art

In semiconductor manufacturing processes, high cleanliness is maintained in an inside of a pod configured to contain wafers, and in an inside of a mini-environment through which the wafers are inserted into and removed from the pod and transferred into each processing apparatus. With this, what is called a yield is increased in the semiconductor manufacturing processes. In order to maintain the high cleanliness, as disclosed in Japanese Patent No. 3,581,310, there has been known a configuration of suppressing an atmosphere in an external space from entering the mini-environment or the like. Further, wiring has been thinned along with revision of what is called design rules for semiconductors. As a result, in recent years, there has been a growing demand to take measures against a natural oxide film that has not been problematic. In Japanese Patent Nos. 4,301,456 and 4,309,935, there is disclosed a configuration of suppressing partial pressure of oxygen in an atmosphere at the time when the wafers are inserted into and removed from the pod and under a state in which the wafers are contained in the pod. With this configuration, a gas in the pod is replaced as appropriate so as to suppress partial pressure of an oxidizing gas, thereby being capable of suppress generation of the natural oxide film.

Further thinning of wiring along with recent revision of the design rules has been increasing a stricter demand to suppress generation of the natural oxide film. In view of the circumstances, there has been proposed a system of introducing what is called dry nitrogen or the like into the above-mentioned mini-environment so as to suppress the partial pressure of the oxidizing gas in the mini-environment. In order to meet such a demand, it is generally preferred that a satisfactory management environment of the wafers be provided by employing new load port apparatus or the like. However, due to the recent request for greater cost reduction in the field of semiconductor, there has been a demand for a method applicable also to the current load port apparatus as exemplified in Japanese Patent No. 3,581,310 and capable of suppressing the partial pressure of the oxidizing gas as described above.

### SUMMARY OF THE INVENTION

The present invention has been made in view of the circumstances described above, and it is a main object thereof to provide a load port apparatus having the structure that is easily applicable to the related-art load port apparatus and capable of suppressing a partial pressure of an oxidizing gas in a mini-environment.

In order to achieve the above-mentioned object, according to one embodiment of the present invention, there is provided a load port apparatus configured to open and close a lid of an opening of a pod so that an object to be processed is insertable into and removable from the pod through a mini-environment, the load port apparatus being installed together with a processing apparatus for the object to be processed so that the object to be processed is transportable from the pod to the processing apparatus through the mini-environment, the load port apparatus including: a main base configured to partition the mini-environment from an external space, the main base including an opening portion facing the opening of the pod and communicating the mini-environment to the external space; a door configured to open and close the opening portion and hold the lid; and a flexible sealing plate arranged so as to project from the main base toward an inside of the opening portion, the flexible sealing plate being configured to abut against an abutment surface surrounding the opening of the pod.

Not that, in the above-mentioned load port apparatus, it is preferred that the flexible sealing plate be bent on an inner peripheral side of the flexible sealing plate by a predetermined angle toward the external space. Alternatively, it is preferred that the flexible sealing plate project on an inner peripheral side of the flexible sealing plate with an inclination of a predetermined angle toward the external space. Further, in this case, it is preferred that the predetermined angle be set to at most 65 degrees. Further, in the above-mentioned load port apparatus, it is preferred that the inner peripheral edge of the flexible sealing plate be positioned on the external space side with respect to a position of the abutment surface of the pod, at which the lid is to be opened and closed. Further, it is preferred that the flexible sealing plate be made of a resin, or that the flexible sealing plate be made of a metal. In addition, it is preferred that the flexible sealing plate have a slit formed in a region from an inner peripheral edge of the flexible sealing plate toward an inner periphery of the opening portion.

According to the one embodiment of the present invention, the partial pressure of the oxidizing gas in the mini-environment can be suppressed. Further, the present invention can be applied also to the related-art load port apparatus by adding the simple structure. With this, the related-art apparatus can be easily applied to future semiconductor manufacturing processes.

Further features of the present invention will become apparent from the following description of exemplary embodiments with reference to the attached drawings.

### BRIEF DESCRIPTION OF THE DRAWINGS

FIG. 1 is a schematic view of a state in which a pod is mounted on a load port apparatus according to an embodiment of the present invention.

FIGS. 2A and 2B are schematic enlarged views of a main part of FIG. 1.

FIG. 3 is a view of a state in which an opening portion of the load port apparatus illustrated in FIG. 1 is viewed from a mount base side.

FIG. 4 is a view of an example of a bending angle of a sealing plate.

FIGS. 5A and 5B are views of examples of the structure of the sealing plate at a part corresponding to a corner portion of the opening portion illustrated in FIG. 3.

FIGS. 6A, 6B and 6C are views of sealing plates according to other embodiments of the present invention.

FIGS. 7A and 7B are views of a sealing plate according to still another embodiment of the present invention.

### DESCRIPTION OF THE EMBODIMENTS

Preferred Embodiments of the Present Invention will now be described in detail in accordance with the accompanying drawings.

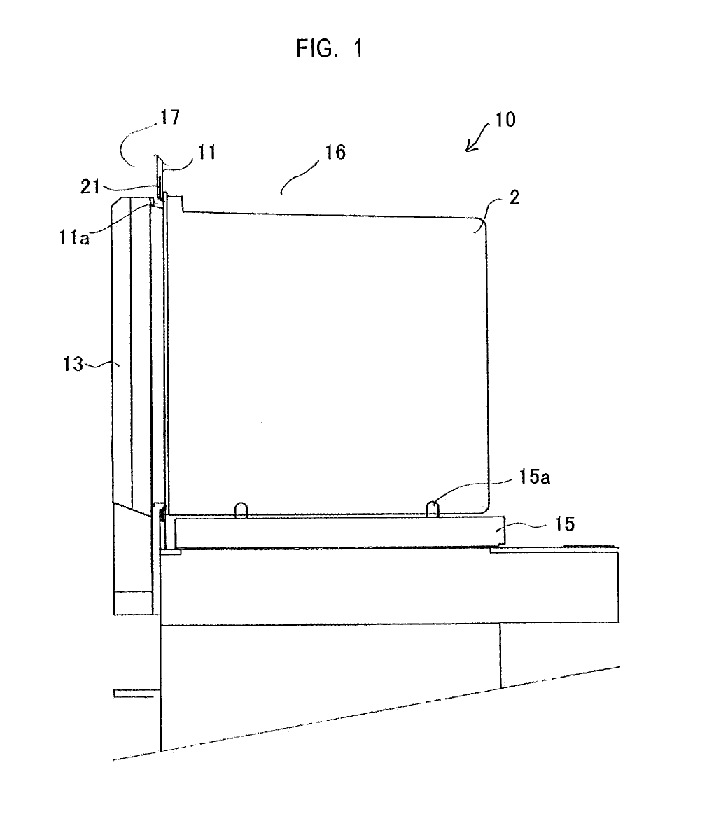

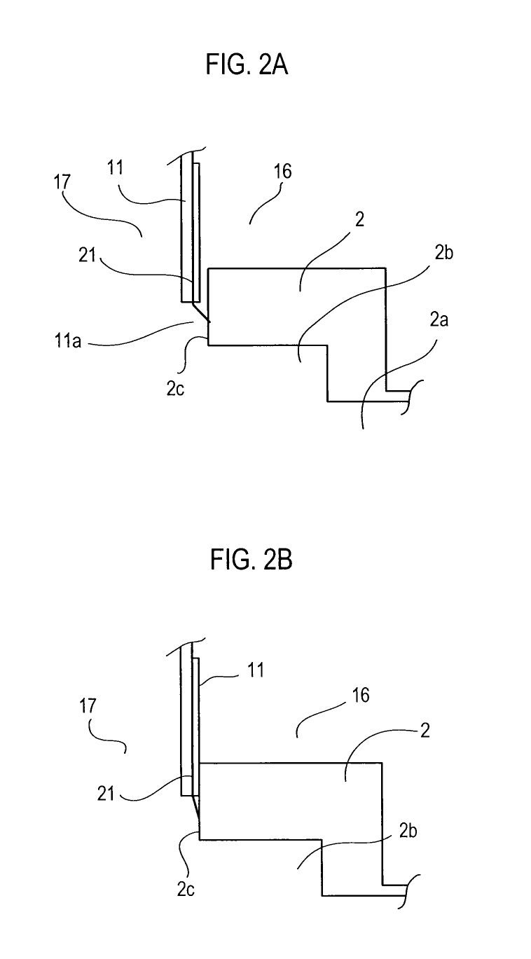

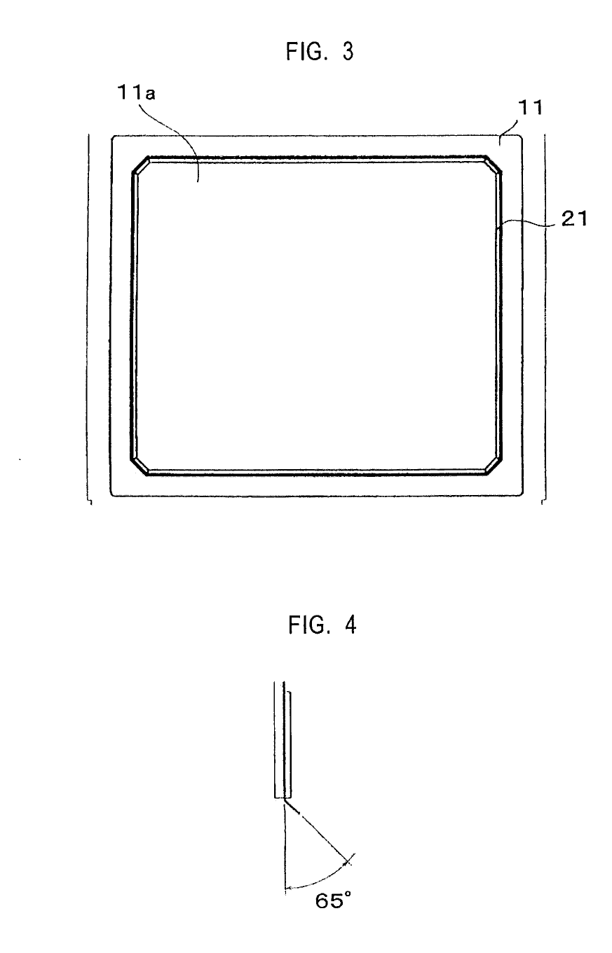

Now, an embodiment of the present invention is described with reference to the drawings. FIG. 1 is a schematic view of a load port apparatus according to an embodiment of the present invention as viewed in a cross-section taken along a driving trajectory of a door under a state in which a pod is mounted. FIGS. 2A and 2B are enlarged views of a main part of FIG. 1, for illustrating action of a sealing plate in conjunction with movement of the pod. FIG. 3 is a schematic configuration view of a state in which an opening portion is viewed from a mini-environment side.

As illustrated in FIG. 1, a load port apparatus according to this embodiment includes, as main components, a main base 11, a door 13, and a mount base 15. The main base 11 partitions an external space 16 and a mini-environment 17 from each other. A pod 2 is transported in the external space 16, and the door 13 and a wafer transportation robot (not shown) are arranged in the mini-environment 17. Further, the main base 11 includes an opening portion 11a that is substantially closed by the door 13 and communicates the external space 16 and the mini-environment 17 to each other. The door 13 is capable of moving close to and away from the opening portion 11a so as to close and open the opening portion 11a, and is also capable of retracting from a space in front of the opening portion 11a. Further, the door 13 is also capable of holding and opening a lid (not shown) of the pod 2. When the door 13 moves away from the opening portion 11a while holding the lid, the opening of the pod 2 is opened. In addition, when the door 13 retracts downward from the front of the opening portion 11a, wafers can be inserted into and removed from the pod 2 by the transportation robot (not shown) arranged in the mini-environment 17.

The mount base 15 is arranged in front of the opening portion 11a, and the pod 2 is mounted thereon. Positioning pins 15a are arranged in a surface of the mount base 15. With this, at the time of mounting the pod 2, a relative positional relationship between the pod 2 and the mount base 15 is uniquely determined. Further, the mount base 15 is capable of moving close to and away from the opening portion 11a. With this, the pod 2 is mounted at a distant position, whereas the lid of the pod 2 is opened and closed by the door 13 at a close position so that the wafers are inserted and removed.

The pod 2 exemplified in this embodiment has a standard shape to be used for a semiconductor manufacturing process. The pod 2 includes a wafer containing space 2a, a lid receiving space 2b, and an outer peripheral flange portion 2c (refer to FIGS. 2A and 2B). The wafer containing space is a space for actually containing a plurality of wafers as objects to be processed, and is defined as a main space in the pod 2. The lid receiving space is defined between the wafer containing space and the external space so as to receive the lid. The lid receiving space has an opening that is larger in both vertical and horizontal directions than the wafer containing space. The outer peripheral flange portion surrounds a periphery of the lid receiving space to form an abutment surface to be brought into abutment against a sealing member described later. In this embodiment, the outer peripheral flange portion is formed of a flat surface.

In this embodiment, a sealing plate 21 is arranged in addition to the main components of the load port apparatus 10. The sealing plate 21 projects from the main base 11 toward an inside of the opening portion 11a. As illustrated in FIG. 3, the sealing plate 21 has a frame-like shape, and is connected to the main base 11 at an outer peripheral side or outer peripheral edges thereof. Further, inner peripheral edges of the sealing plate 21 project toward the external space side with an inclination of a predetermined angle toward the external space 16 side with respect to an extended plane of the opening portion 11a. Note that, FIG. 3 is a view of the opening portion 11a as viewed from the external space 16 side in which the mount base 15 is arranged. Further, in this embodiment, the sealing plate 21 is flexible enough to be easily deflected toward the inner space 17 side by a driving force at the time when the mount base 15 drives the pod 2 mounted thereon toward the opening portion 11a side, or by a pressing force at the time when the base 15 presses the pod 2 toward the inner space 17 side.

Actual movement of the sealing plate 21 is described with reference to FIGS. 2A and 2B. The pod 2 is mounted on the mount base 15 that is located at what is called a loading/unloading position of the pod 2. In this state, the mount base 15 moves the pod 2 toward the opening portion 11a side. The inner peripheral edges of the sealing plate 21 project toward the external space side with respect to an external surface of the main base 11 forming the opening portion 11a. Thus, in the middle of the movement of the pod 2, as illustrated in FIG. 2A, the abutment surface of the flange portion 2c first abuts against the inner peripheral edges of the sealing plate 21. In this state, the pod 2 is further moved until the abutment surface abuts against the external surface of the main base 11, and then the movement of the pod 2 is stopped. At this time, as illustrated in FIG. 2B, the flexible sealing plate 21 is deflected by the pressing force from the abutment surface. With this, the abutment surface is brought into closer contact with the inner peripheral edges or the surface of the sealing plate 21.

When the state described above is maintained, a gap between the outer peripheral flange portion 2c of the pod and the periphery of the opening portion 11a is sealed by the sealing plate 21. With this, a gas that is controlled in partial pressure of an oxidizing gas is prevented from leaking from the mini-environment 17 to the external space 16. Note that, in order to maintain a posture of the projecting sealing plate 21 on lateral sides or a bottom side of the opening portion 11a, the sealing plate 21 used in this embodiment is made of a metal or formed of a metal plate in consideration of a necessary projecting amount or the like. From the viewpoint of, for example, whether or not a uniform bending angle or a uniform inclination angle can be easily formed in the process, it has been proved that an angle of 65 degrees or less is preferred as an appropriate angle as illustrated in FIG. 4. An appropriate posture is difficult to maintain at a bending angle of more than 65 degrees, and hence the sealing plate 21 is less likely to be deflected in conformity with the abutment surface. Further, an internal pressure of the mini-environment 17 is set to be slightly higher than the atmospheric pressure in the external space 16. Therefore, the predetermined angle is set also in expectation of increase in pressing force to be applied from the sealing plate 21 to the abutment surface by this pressure difference. When such an aspect is taken into consideration, it is preferred that the predetermined angle be set to 25 degrees or more.

Note that, the sealing plate 21 exemplified in this embodiment is made of a metal or formed of a metal plate, but the same effects can be obtained also with use of a resin, rubber, or a composite material thereof. Specifically, in consideration of processability and an influence on the abutment surface against the pod, it is preferred that the sealing plate 21 be made of a resin, rubber, or the like. In a case where a metal member is used, depending on properties of a selected metal material, a metal member subjected to a thinning process needs to be used so as to secure the flexibility. However, in a case of a member made of a resin, rubber, or the like, such a process is unnecessary in many cases, or even when the process is performed, the process is facilitated. Thus, a member made of a resin, rubber, or the like is more advantageous than the metal member. Further, the pod 2 to be brought into abutment against the sealing plate 21 is generally made of a resin material such as plastics. Thus, when a metal sealing member is used, the metal sealing member to be selected may be required to have such hardness that the abutment surface is not cut due to interference between the sealing member and the abutment surface of the pod. However, the sealing member made of a resin has an advantage in that the risk of cutting of the pod due to the material hardness as described above need not be taken into consideration.

Meanwhile, in a case where the sealing member is made of a resin, rubber, or the like, static electricity may influence the sealability. Thus, when such an influence of the static electricity on the sealability is taken into consideration, it is preferred that the metal sealing member be used, or rubber having conductivity be used as a raw material.

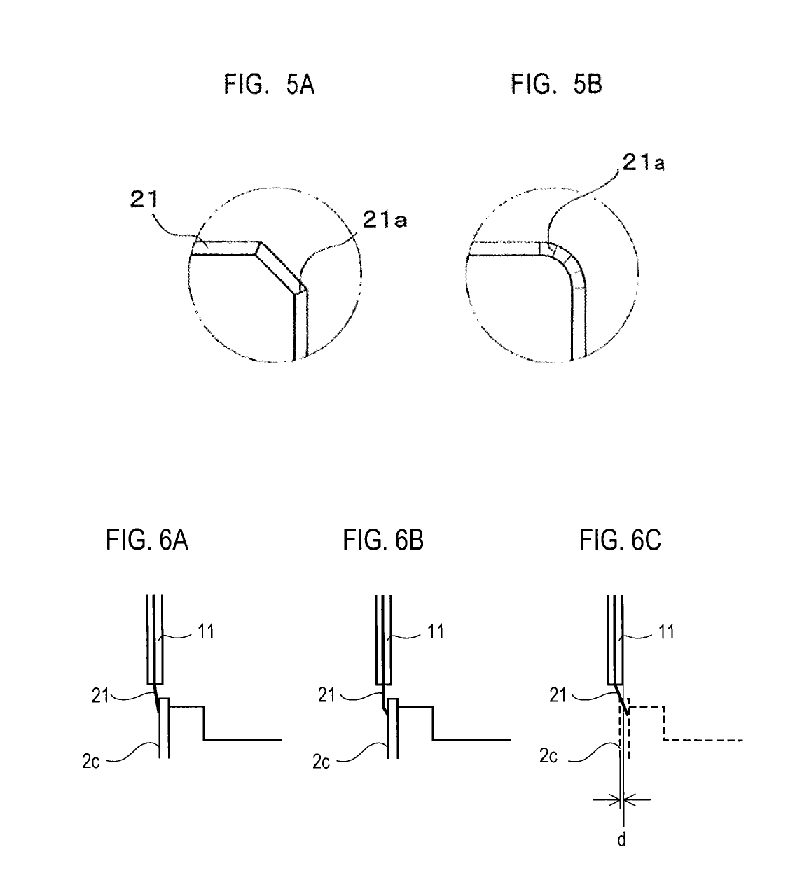

The opening portion 11a includes corner portions, and the flexibility is suppressed at the corner portions due to the predetermined angle maintained as described above. Therefore, in this embodiment, slits 21a are formed as illustrated in FIGS. 5A and 5B. When five slits 21a are formed as illustrated in FIG. 5B instead of two slits 21a illustrated in FIG. 5A, the sealing plate 21 conforms to the abutment surface more satisfactorily. However, increase in the number of the slits 21a results in increase in the number of gas leakage paths. Thus, it is preferred that the number of the slits 21a be changed as appropriate in consideration of the above-mentioned pressure difference, an amount of gas to be supplied to the mini-environment 17, and an allowable leakage amount. However, in a case where the sealing plate 21 can be formed of a material that allows appropriate flexibility to be secured at the corner portions, it is more preferred that the slits 21a be omitted.

In this embodiment, the sealing plate 21 is fixed by being sandwiched between a plate portion of the main base 11 and a body portion of the main base 11. In this case, a surface of the plate portion of the main base 11 on the external space 16 side is defined as a surface of the main base 11, which defines positions of the above-mentioned inner peripheral edges of the sealing plate 21. Further, the sealing plate 21 is bent along a boundary between a sandwiching portion and a non-sandwiching portion. However, the embodiment of the present invention is not limited to those forms. The sealing plate 21 may be fixed by other various fixing methods such as welding and bonding with an adhesive or the like. Further, the bent portion need not be straight in cross-section, bug may be curved in cross-section as illustrated in FIG. 6A, or a distal end portion thereof may be partially bent as illustrated in FIG. 6B.

Note that, in those cases, as illustrated in FIG. 6C, it is preferred that the inner peripheral edges of the sealing plate 21 be positioned on the external space 16 side with respect to a position of the abutment surface of the pod 2, at which the lid is to be opened and closed. With this, the abutment surface and the inner peripheral edges reliably abut against each other at the time of movement of the pod 2. In recent semiconductor manufacturing processes, wafers having larger diameters and the pod 2 upsized in accordance therewith have been employed. When the pod 2 is upsized, the above-mentioned abutment surface may be curved significantly or deformed in other ways depending on processing accuracies or due to aging and the like. Also in such cases, when the flexibility is sufficiently secured and the bending angle and arrangement of the inner peripheral edges are adjusted as appropriate, the sealing plate 21 can satisfactorily conform to the abutment surface so that the inner peripheral edges can abut against a front side of the abutment surface.

Further, in the embodiments described above, the metal is exemplified as a material for the sealing plate 21. However, the present invention is not limited to the use of the metal material, and the flexible materials such as the resin and the rubber may be used as long as shapes can be maintained and the sealing effect can be obtained during contact with the abutment surface. In this case, it is preferred that the sealing plate 21 be bent by the predetermined angle as described above, but the sealing plate 21 need not be bent in that way as long as the sealing effect can be sufficiently obtained.

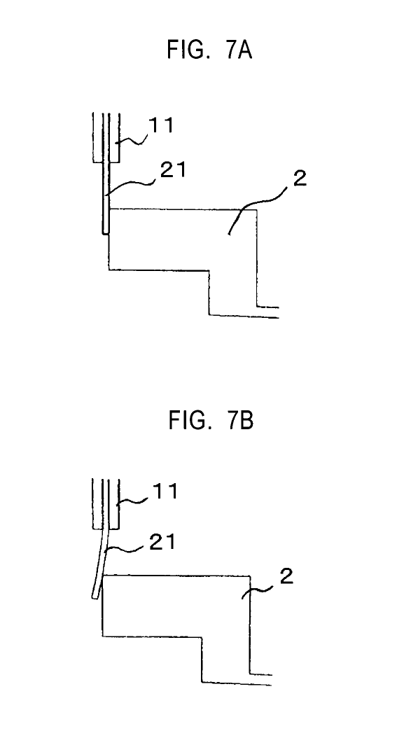

FIGS. 7A and 7B are views of still another embodiment of the present invention, for schematically illustrating how the sealing is performed as in FIGS. 2A and 2B. Note that, in this embodiment, the components having the same functions and effects as those in FIGS. 2A and 2B are denoted by the same reference symbols, and not described in detail. The sealing plate 21 used in this embodiment is formed of a simple resin plate. FIG. 7A illustrates a state in which the abutment surface abuts against the sealing plate 21, and FIG. 7B illustrates a state in which the pod 2 has been further moved and stopped. In this embodiment, the sealing plate 21 itself can be easily processed, and the slits need not be formed at the corner portions. With this configuration, when the entire abutment surface is brought into the abutting state illustrated in FIG. 7A, significantly excellent sealability can be obtained. However, when a part of the abutment surface is brought into the state illustrated in FIG. 7B, an internal gas may leak out through this part. Therefore, it is preferred that the flexibility be set to be higher than that of the sealing plate 21 used in the above-mentioned embodiments.

As described above, the present invention provides the flexible sealing plate 21 for a load port apparatus configured to open and close the lid of the opening of the pod 2 so that wafers are insertable and removable through the mini-environment 17. The load port apparatus is installed together with a wafer processing apparatus so that the wafers are transportable from the pod 2 to the processing apparatus through the mini-environment 17. The flexible sealing plate 21 is arranged so as to project from the main base toward an inside of the opening portion, and to abut against the abutment surface surrounding the opening portion of the pod. By arranging the sealing plate 21 in this way, that is, only by adding the simple structure to the related-art load port apparatus, leakage of an inert gas such as nitrogen from the mini-environment 17 can be suppressed while maintaining an environment of what is called clean transportation.

As described above, the present invention relates to a load port apparatus that is suited for use with semiconductor processing apparatus. However, the present invention is applicable not only to the semiconductor processing apparatus, but also to what is called load port apparatus to be used with various processing apparatus in which various processes are performed on objects like the semiconductor, such as a processing apparatus for panels of liquid crystal displays. Thus, it is preferred that the wafers, the pod, and the semiconductor processing apparatus in the embodiments described above be interpreted respectively as objects to be processed, a container configured to contain various objects to be processed, and a processing apparatus configured to perform processes on the objects to be processed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-000100, filed Jan. 6, 2014, which is hereby incorporated by reference herein in its entirety.

What is claimed is:

1. A load port apparatus configured to open and close a lid of an opening of a pod so that an object to be processed is insertable into and removable from the pod through a mini-environment, the load port apparatus being installed together with a processing apparatus for the object to be processed so that the object to be processed is transportable from the pod to the processing apparatus through the mini-environment, the load port apparatus comprising:
a main base configured to partition the mini-environment from an external space, the main base comprising an opening portion facing the opening of the pod and communicating the mini-environment to the external space;
a door configured to open and close the opening portion and hold the lid; and
a flexible sealing plate arranged so as to project from the main base toward an inside of the opening portion, the flexible sealing plate being configured to abut against an abutment surface surrounding the opening of the pod.

2. A load port apparatus according to claim 1, wherein the flexible sealing plate is bent on an inner peripheral side of the flexible sealing plate by a predetermined angle toward the external space.

3. A load port apparatus according to claim 1, wherein the flexible sealing plate projects on an inner peripheral side of the flexible sealing plate with an inclination of a predetermined angle toward the external space.

4. A load port apparatus according to claim 2, wherein the predetermined angle is set to at most 65 degrees.

5. A load port apparatus according to claim 3, wherein the predetermined angle is set to at most 65 degrees.

6. A load port apparatus according to claim 1, wherein the inner peripheral edge of the flexible sealing plate is positioned on the external space side with respect to a position of the abutment surface of the pod, at which the lid is to be opened and closed.

7. A load port apparatus according to claim 1, wherein the flexible sealing plate is made of a resin.

8. A load port apparatus according to claim 1, wherein the flexible sealing plate is made of a metal.

9. A load port apparatus according to claim 1, wherein the flexible sealing plate has a slit formed in a region from an inner peripheral edge of the flexible sealing plate toward an inner periphery of the opening portion.
